(19) United States
(12) Patent Application Publication
(10) Pub. No.: US 2004/0002299 A1
(43) Pub. Date: Jan. 1, 2004

(54) Ventilation system and method of using

(75) Inventors: Mu-Tsang Lin, Changhua (TW); Yu-Chih Liou, Kaohsiung (TW); Tu-Yi Chiu, Kaohsiung (TW); Ji-Liang Wu, Kaohsiung (TW); Wie-Liang Tsai, Kaohsiung (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/185,864

(22) Filed: Jun. 27, 2002

(51) Int. Cl. H05K 5/00; B65G 49/07

(52) U.S. Cl. 454/184; 414/935

(57) ABSTRACT

The present invention provides a ventilation system and method that operates to remove outgassing of chemicals formed on a wafer during a wafer fabrication process to prevent contamination in a sealed wafer handling chamber. More particularly, the present invention discloses a ventilation system having a hood body having a gas supply conduit attached to a sealed outer side chamber of the ventilation hood such that contaminating particles in an interior of the hood are carried out by a purge gas flown into the hood interior through an inlet of the hood connected to the gas supply conduit into a facility vacuum exhaust system attached to an outlet of the hood. Preferably, the chamber is a load-lock chamber that operates to perform load lock processing on wafers and further operates to load and unload wafers to another location for further processing after using the ventilation system.

### FIELD OF THE INVENTION

The present invention generally relates to a ventilation system for use in preventing contamination of a wafer fabrication process and a method of using the ventilation systems and more particularly, relates to a ventilation hood for use in preventing contamination of a semiconductor fabrication environment from outgassing of chemicals etched and deposited on a wafer surface.

### BACKGROUND OF THE INVENTION

In the fabrication of semiconductor integrated circuit (IC) devices, various device features such as insulation layers, metallization layers, passivation layers, etc., are formed on a semi-conducting substrate. It is known that the quality of an IC device fabricated is a function of the processes in which these features are formed. The yield of an IC fabrication process is in turn a function of the quality of the device fabricated and a function of the cleanliness of the manufacturing environment in which the IC device is processed.

The ever increasing trend of miniaturization of semiconductor IC devices occurring in recent years requires more stringent control of the cleanliness in the fabrication process or the processing chamber in which the process is conducted. This leads to a more stringent control of the maximum amount of impurities and contaminants that are allowed in a process chamber. When the dimension of a miniaturized device approaches the sub-half-micron level, even a minutest amount of contaminants can significantly reduce the yield of the IC manufacturing process. For instance, the yield of the process can be drastically reduced by the presence of contaminating particles during deposition or etching of films which leads to the formation of voids, dislocations or short-circuits resulting in performance and reliability problems in the IC devices fabricated.

In recent years, contamination caused by particles or films has been reduced by the improvements made in the quality of clean rooms and by the increasing utilization of automated equipment, which are designed to minimize exposure to human operators. However, even though contaminants from external sources have been reduced, various contaminating particles and films are still generated inside a process or load lock chamber during processing of semiconductor wafers. Some possible sources of contamination that have been identified include the process gases and liquids, the interior walls of the process chambers and the mechanical wear of the wafer handling equipment.

The chances of generating contaminating particles are also increased in process chambers that are equipped with plasma enhancement. Various chemically reacted fragments are generated from the processing gases, which include ions, electrons and radicals. These fragments can combine and form negatively charged particles, which may ultimately contaminate a substrate that is being processed in the chamber. Various other materials, such as polymeric films may be coated on the process chamber walls during plasma processing. The films may dislodge and fall from the process chamber walls when subjected to mechanical and thermal stresses onto the wafers that are being processed in the chamber.

Conventionally, a wet cleaning process must be conducted in a semiconductor process chamber as part of a preventive maintenance schedule. For instance, in a chemical vapor deposition (CVD) chamber, a preventive maintenance schedule, which included a wet cleaning, is conducted on a monthly basis. The wet cleaning process can be carried out by using cleaning solvents such as IPA (isopropyl alcohol), deionized water, IPA/deionized water mixture, or the more volatile acetone. A wet cleaning process is time consuming and generally hazardous to a maintenance personnel who carries out the process due to the toxic nature of the residual reactant gases, the reaction byproducts and the cleaning solvent used. For instance, in a wet cleaning process for a chemical vapor deposition chamber that was utilized for depositing tungsten plugs, the cleaning procedure must be carefully carried out due to the toxic nature of tungsten fluoride reactant gas used in the chamber and the possibility of encountering residual reactant gas during the cleaning process.

Similarly, in a process chamber for depositing high temperature films (HTF), highly toxic reactant gases are also used which make the chamber cleaning process a hazardous task. In these process chambers, the contaminating substances may be in the form of either particulates or fumes. For instance, in a semiconductor process chamber, the particulate sources may include silicon dust, quartz dust, atmospheric dust, and particles originating from clean room personnel and processing equipment. Some of the examples of fume contaminants are solvent residues such as from acetone, isopropyl alcohol, methyl alcohol, xylene, photoresist developer residues from dissolved photoresist materials, oil fumes introduced through improperly filtered air or gas lines, metallic etchant or photoresist strip baths.

A typical wafer processing system, an Applied Materials Centura® wafer processing and handling system 10 is shown in FIG. 1. The wafer processing and handling system 10 generally has three processing chambers 20, 22, 24, two load lock chambers 12, 14, a wafer transferring device 16, and an orientation chamber 36. The three processing chambers perform etching and deposition of wafers during a semiconductor manufacturing process.

A closer view of one of the load lock chambers is shown in FIG. 2. FIG. 2 shows a plan view of the inside of load lock chamber 12 in communication with a cassette loading and transferring device 38 and in further communication a buffer chamber 26 for communicating wafers to and from the load lock chamber 12 to another location. A plurality of wafers 34, typically 25, is loaded into a wafer cassette 30 for processing within the load lock chamber 12. The buffer chamber 26 selectively unloading or loads single wafer from or into the load lock chamber 12. The load lock chamber 12 may be used to further process processed wafers and to load and unload wafers communicated from the processing chambers through the wafer processor and handling system 10. However, during the loading and unloading of the plurality of processed wafers 34, outgassing from the processed wafers 34 may occur. Such outgassing results from toxic chemicals, such as HBr deposited on wafer surfaces and may cause corrosion of the load lock chamber inducing load lock particles to form at a contamination level above 9 ppm in the fabrication process, thus significantly reducing wafer per hour production.

The load lock chamber 12 may perform a load lock process such as a wafer pressure equalization process on the plurality of wafers 34. The load lock chamber 12 may further perform a heating process by using a corrosion resistance kit or a diffusion system as shown in FIG. 3 to reduce outgassing of processed wafers within the load lock chamber 12. However, the heating process does not completely eliminate load lock particles formed as a result of toxic chemicals, such as HBr deposited on wafer surfaces. Additionally, the load lock chambers 12, 14 are cleaned about twice a day allowing the particle fail rate to be reduced by 10% during the cleaning period. However, an improved system is needed to eliminate the contamination caused by outgassing of wafer particles during loading and unloading of a load lock chamber.

Therefore, it is an object of the present invention to remove outgassing from wafer surfaces disposed within a sealed chamber before transferring wafers to another wafer processing chamber.

It is a further object of the present invention to use a ventilation system and method to build an airtight space within a load lock chamber to reduce moisture within the chamber to prevent corrosion and to remove wafer outgassing.

It is a further object of the present invention to provide a ventilation system that does not require modification of electrical controls for processing chambers or loadlock chambers.

It is an object of the present invention to reduce HBr outgassing within a load lock chamber to reduce particle fail rate from more than 9 ppm to 0 ppm.

It is an object of the present invention to prevent surface corrosion of load lock chambers.

It is therefore an object of the present invention to provide a contamination reducing ventilation system for use in preventing contamination of a load lock chamber that does not have the drawbacks or shortcomings of the conventional contamination prevention systems.

It is another object of the present invention to provide a ventilation hood equipped with an access door for cleaning a load lock or process chamber that does not require the manual operation of an air gun inside the hood by an operator and thereby eliminating the risk of exposure to hazardous components of the exhaust.

It is a further object of the present invention to provide a ventilation hood that can be used effectively to remove hazardous fumes and contaminating particles from a sealed load lock or process chamber prior to conducting a wet cleaning process on the chamber.

It is another further object of the present invention to provide a ventilation hood for use in ventilating a process chamber or load lock chamber prior to wafer transfer that is constructed of a substantially clear material such that the cleaning process can be visually observed.

It is still another object of the present invention to provide a ventilation hood for use in cleaning a process or load lock chamber that is equipped with a gas purge and exhaust system.

It is still another further object of the present invention to provide a ventilation hood for use in cleaning a process or load lock chamber that is equipped with a gas flow conduit inside the hood such that a purge gas can be flown through the hood and the chamber to carry away contaminating particles.

It is yet another further object of the present invention to provide a method for venting a load lock chamber prior to loading or unloading of wafers from the load lock chamber by flowing into the hood and the process chamber a purge gas simultaneously with the vacuum evacuation process such that substantially all contaminating particles are removed from the chamber.

### SUMMARY OF THE INVENTION

In accordance with the present invention, a ventilation system and method having enhanced particulate control is utilizing to prevent contamination within a sealed processing or load lock chamber.

In a preferred embodiment, an apparatus for cleaning a wafer loading device is provided which includes a ventilation hood that has a hood body, the body having an open bottom portion, the bottom portion being adapted to sealingly engage a wafer holding device, a top portion, the top portion forming an airtight horizontally disposed top chamber, and a middle portion vertically juxtaposed between the top portion and the bottom portion, the middle portion further having an airtight outer side chamber, wherein the top portion, the middle portion, and the open bottom are in communication and cooperate to define a hood interior, the interior forming a sealed inner chamber when the open bottom portion sealingly engages a wafer holding device; a gas supply conduit attached to outer side chamber for supplying a purge gas from a gas supply source through the enclosed outer side chamber and into the interior of the hood body; an exhaust system connected to the top chamber of the hood body for removing the purge gas from the sealed chamber; and means for evenly distributing a purge gas through the hood body. The means for evenly distributing a purge gas through the hood body may have a plurality of distribution holes spaced apart and disposed within an inner lower wall of the top portion and within an inner side wall of the hood middle portion.

A method for using a ventilation system to eliminate load lock contamination particles within a load-lock chamber has the steps of first providing a load-lock chamber in communication with a processing chamber, the load lock chamber having a movable wafer holding member capable of moving between a first retracted position for loading and unloading wafers to a second extended position for ventilating outgassing from wafers. Next, providing a ventilation hood having a hood body equipped with an open bottom portion having a peripheral edge adapted to sealingly engage the wafer holding member, wherein the open bottom portion is positioned above the wafer holding member, a top portion forming an upper chamber, the upper chamber having an exterior upper wall, the exterior upper wall has an outlet in communication with an exhaust tube for communicating a purge gas from the hood to the atmosphere or to a facility exhaust vacuum, and an inner lower wall spaced downwardly apart from the exterior upper wall, the inner lower wall having a plurality of distribution holes disposed therewithin, a middle portion having an outer side chamber, the outer side chamber having an exterior side wall, an inner side wall spaced inwardly apart from the exterior side wall, the inner side wall having a plurality of distribution holes disposed therewithin, and an inlet in fluid communication with a gas supply conduit for communicating a purge gas from a gas supply source to an interior of the hood. The next steps include:

loading a wafer cassette holding a plurality of wafers onto the wafer holding member;

performing a processing operation on the plurality of wafers disposed within the load lock chamber;

moving the wafer holding device to the second extended position to sealingly engage a lower peripheral edge of the hood body open bottom;

flowing a purge gas from the gas supply through the inlet of the outer side chamber, then through the inner side wall distribution holes to the plurality of wafers disposed within the hood interior; and

purging an effluent formed from the purge gas and outgassing of chemicals disposed on the plurality of wafers by exhausting the effluent through the outlet of the top chamber to the exhaust tube in communication with the exhaust system.

The method may further include the step of flowing a compressed gas through the ventilation hood continuously for a time period of not less than 5 minutes. The gas flown through the compressed gas inlet can be nitrogen or compressed dry air. The method may further include the step of opening a shut-off valve connected in fluid communication with and in-between the gas conduit and a gas supply source. Preferably, the fluid flows through the compressed gas inlet under a pressure of about 20.

### BRIEF DESCRIPTION OF THE DRAWINGS

These and other objects, features and advantages of the present invention will become apparent from the following detailed description and the appended drawings in which:

FIG. 1 shows a perspective view of a prior art wafer handling and processing system.

FIG. 2 shows a plan view of a prior art cassette transferring device, a load lock chamber, and a wafer buffer chamber.

FIG. 3 shows a plan view of a prior art cassette transferring device, and a load lock chamber having a diffusion system disposed within.

FIG. 4 shows a partial perspective view of a load lock chamber having a ventilation system 100 in accordance with the present invention.

FIG. 5 shows a plan view of gas flow through a ventilation hood body sealably engaging a wafer holder member in accordance with the present invention.

FIG. 6 shows a perspective view of a preferred embodiment in accordance with the present invention.

FIG. 7 shows a perspective view of an alternative preferred embodiment in accordance with the present invention.

FIG. 8 shows a perspective view of a ventilation hood body disposed within a load lock chamber.

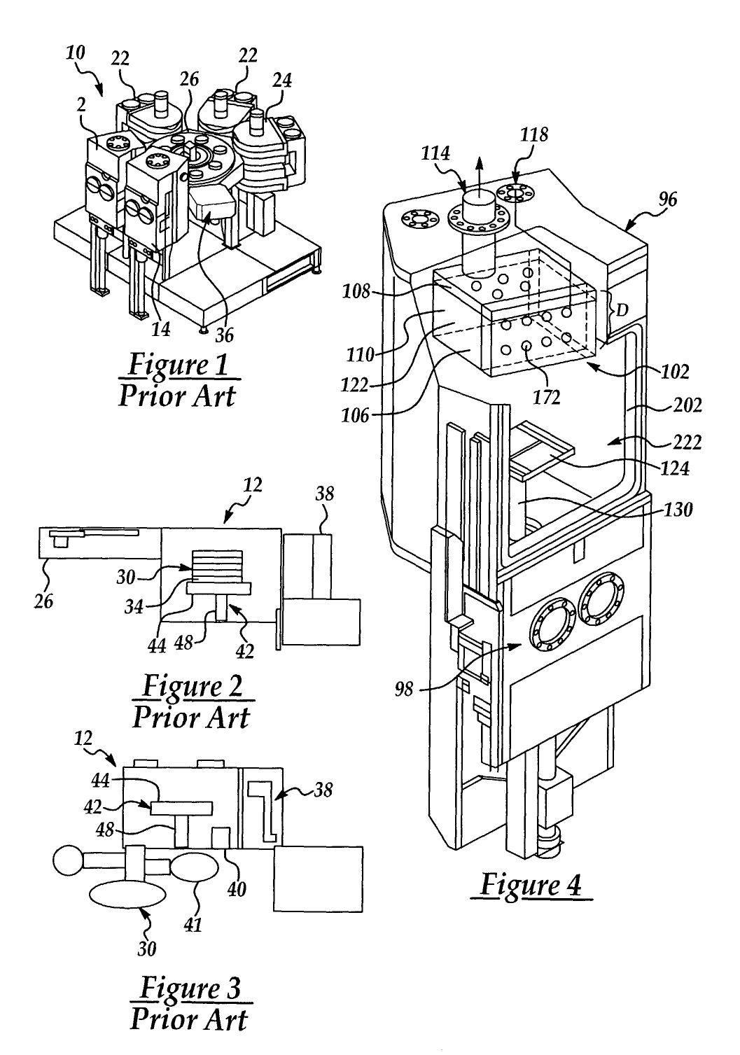

### DETAILED DESCRIPTION OF THE PREFERRED EMBODIMENTS

The present invention operates to remove outgassing of chemicals that have been etched or deposited during a wafer fabrication process from a sealed wafer handling chamber before transferring wafers to another chamber. The present invention provides a ventilation system that builds an airtight space within a sealed wafer handling or processing chamber to remove moisture and outgassing of chemicals previously etched and deposited on wafers during a wafer process by eliminating the contamination particles generated from the outgassing of the wafers. The present invention can reduce outgassing of toxic chemicals, such as HBr, from wafer surfaces of wafers disposed within a load lock chamber from an original particle contamination of more than 9 ppm down to 0 ppm.

More particularly, the present invention discloses a ventilation hood that is used for preventing contamination in a sealed wafer handling chamber and is equipped with a gas supply conduit attached to a sealed outer side chamber of the ventilation hood such that contaminating particles in an interior of the hood are carried out by a purge gas flown into the hood interior through an inlet of the hood connected to the gas supply conduit into a facility vacuum exhaust system attached to an outlet of the hood. Preferably, the sealed chamber is a loadlock chamber having a wafer indexer that operates to load and unload wafers to another location to prepare wafers for further processing in a separate processing chamber. The load-lock chamber may perform a load lock process such as pressurizing wafers loaded within the load lock chamber.

The ventilation hood of the present invention can be advantageously made of a transparent or translucent plastic material. For instance, polymethylmethacrylate (Plexiglass®) or polycarbonate (Lexan®) can be advantageously used. A transparent hood body affords the convenience of observation by a maintenance personnel of the hood interior and the chamber cavity during a cleaning process. The present invention ventilation hood may also be made by any other material that may not be optically transparent such as stainless steel. When such materials are used, an observation door, or an access door made of a transparent or a translucent material may be provided on a front panel of the process chamber. The observation door allows a machine operator to observe through the door the hood interior and the chamber cavity, and furthermore, provides easy access to the chamber interior should additional cleaning by hand becomes necessary. For instance, it may become necessary for the operator to wipe the interior walls of the process chamber with solvents such as IPA or acetone. The access door may also be used for additional purge operation by an operator using an air gun when a purging operation performed using the ventilation hood is insufficient.

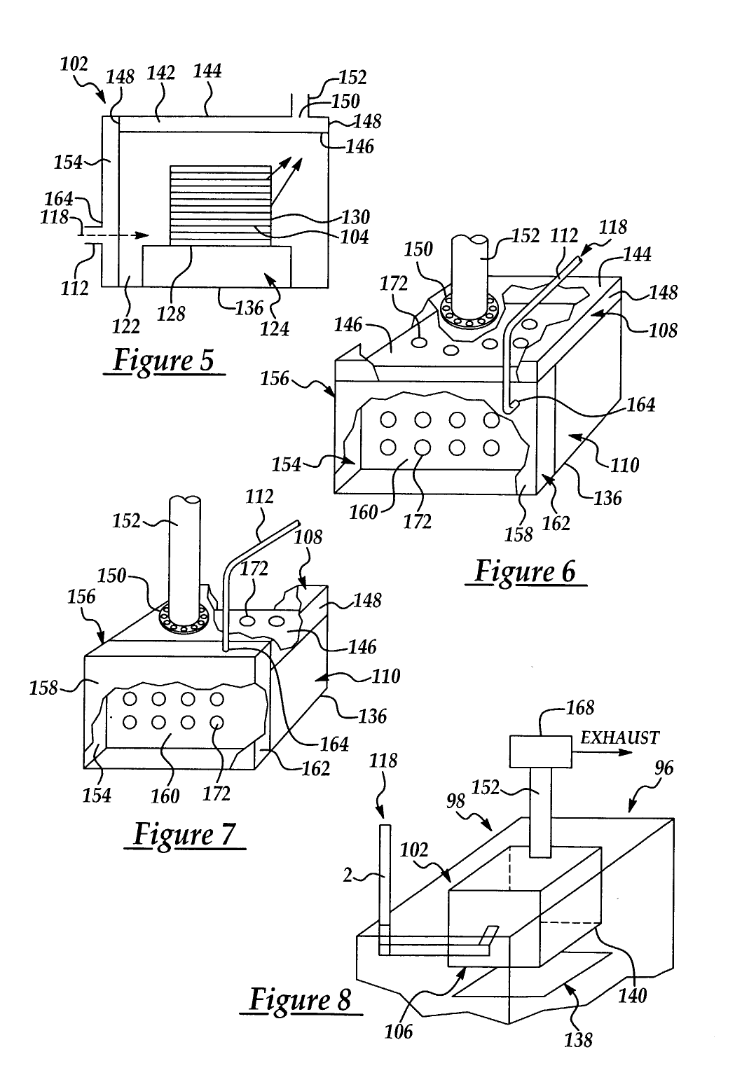

Referring initially to FIGS. 4-8, wherein several views of the ventilation system 100 are shown. More particularly, in FIG. 4, a partial perspective view of a load lock chamber 96 having the ventilation system 100 of the present invention is shown. FIG. 5 is a plan view of the ventilation system 100 of the present invention, the ventilation system having a ventilation hood body 102 sealably engaging a wafer holder member of the load lock chamber 96. FIGS. 6-7 show alternative perspective views according to preferred embodiments of the ventilation system 100. FIG. 8 is a perspective view of the ventilation hood body 102 disposed within the load lock chamber 96. The ventilation system 100 has a ventilation hood body 102 adapted purge contaminants from a plurality of wafers 104 (not shown) disposed within a wafer cassette 132 after a wafer processing operation has been performed on the wafers 104. The hood body 102 as an open bottom portion 106, a top portion 108, a middle portion 110, a gas supply conduit 112 attached to the hood body 102, an exhaust system connected to the top portion 108 of the hood body 102 for removing the purge gas from the sealed chamber, and means for evenly distributing the fluid through the hood body 102. The open bottom portion 106, the top portion 108, and the middle portion 110 cooperate to define a hood interior 122, wherein the hood interior 122 forms a sealed interior chamber when the open bottom portion 106 sealingly engages a wafer holding device 124. The bottom portion 106 being adapted to sealingly engage a movable wafer holding device 124, preferably, the wafer holding device 124 is a cassette load wafer indexer 126 having a substantially flat wafer holding member 128 and a movable arm member 130, the movable arm member 130 capable of moving between a first retracted position and a second extended position, wherein when the movable arm member 130 is in the first retracted position, the wafer cassette 132 may be loaded to or unloaded from a cassette loading device 134, and wherein when the movable arm member 130 is in the second extended position, a peripheral edge 136 of the substantially flat wafer holding member 128 engages the open bottom portion 106 of the hood 102, as shown in FIG. 5. It should be noted that the open bottom portion 106 of the hood body 102 is normally positioned above the substantially flat wafer holder member 128 of the wafer holding device 124. As shown in FIG. 8, the open bottom portion 106 may further have a sealing device, preferably, a leak seal O-ring 138 disposed on a lower peripheral edge 140 of the open bottom portion 106 for sealably engaging the wafer holding device 124. Alternatively, the wafer holding device 124 may have a sealing device specifically designed for sealingly engaging the open bottom portion lower peripheral edge 140.

The top portion 108 forms an airtight horizontally disposed top chamber 116 in fluid communication with the hood interior 122, the top chamber 116 having an upper cover 142 for sealably enclosing the top chamber 116. The upper cover 142 is preferably box-shaped and has an exterior upper wall 144, an inner lower wall 146 spaced downwardly apart from the exterior upper wall 144, and a side peripheral wall 148 peripherally disposed between the exterior upper wall 144 and the inner lower wall 146. The exterior upper wall 144 has an outlet 150 in communication with an exhaust tube 152 for communicating a purge gas from the hood body 102 to the atmosphere or to a facility exhaust vacuum. Preferably, the distance D between the top portion exterior upper wall 144 and the bottom portion lower peripheral edge 140 is 30 cm, as shown in FIG. 4.

The middle portion 110 is vertically juxtaposed between the top portion 108 and the bottom portion 106. The middle portion 110 has an airtight outer side chamber 154 formed thereto. The middle portion outer side chamber 154 has an outer side cover 156 for enclosing the outer side chamber 154. Preferably, the outer side cover 156 is box-shaped and has an exterior side wall 158, an inner side wall 160 spaced inwardly apart from the exterior side wall 158, and an outer peripheral wall 162 peripherally disposed between the exterior side wall 158 and the inner side wall 160. The outer side chamber 154 has an inlet 164 in fluid communication with a gas supply conduit 112 for communicating a purge gas from a gas supply source to the hood interior 122. The inlet 164 may either be located in the exterior side wall 158 as shown in FIG. 6 or in an upper surface of the outer peripheral wall 162 as shown in FIG. 7.

As shown in FIG. 6, in a preferred embodiment, the top portion 108 extends a full width of the hood body 102, wherein an end portion of the inner lower wall 146 is juxtaposed above an upper surface of the outer side chamber outer peripheral wall.

As shown in FIG. 7, in an alternative embodiment, the top portion exterior upper wall 144 is co-planar with the upper peripheral edge of the outer side chamber 154 such that a portion of the top portion side peripheral wall 148 is juxtaposed adjacent to an upper end portion of the middle portion inner side wall 160. Thus, the top portion 108 does not extend the full width of the hood body 102.

The gas supply conduit 112 is attached to the exterior outer side wall of the middle portion outer side chamber 154 for supplying a purge gas from a gas supply source through the enclosed outer side chamber 154 and into the interior of the hood body 102. A suitable material used for the gas supply conduit 112 is Teflon® for its superior chemical and corrosion resistance.

A manual shut-off valve 166 (not shown) or an automatic shut-off valve controlled by a load-lock machine microprocessor may be mounted outside the ventilation hood body 102 in-between the gas supply conduit 112 and a gas supply line or a gas supply reservoir. In the case when a general nitrogen gas is used, the shut-off valve 166 may be connected to a facility nitrogen supply line or a nitrogen supply tank.

The purge gas is capable of removing contaminating particles in a sealed wafer handling chamber cavity and thus reducing the contamination of the clean room environment and fabrication process. A purge gas of general nitrogen or compressed dry air may be flowed through gas supply conduit 112 and then through wafers in a wafer cassette to either loosen the contaminating films or particles on the wafers and chamber walls or those in the chamber cavity such that the particles or films are carried away into the facility vacuum exhaust system. The purge gas used in the present invention novel method can be conveniently a general nitrogen gas, a dry nitrogen gas, or a compressed dry air. Other inert gases such as argon or helium may also be suitably used, even though at substantially higher cost. Next to the shut-off valve 166, which is either a manual type or an automatic type controlled by the machine microprocessor, is mounted a quick connector valve for easy connection to a factory gas supply line or to a gas supply tank. A suitable gas pressure to be used is approximately between about 20 psi for compressed dry air.

The exhaust tube 152 is connected to the top chamber outlet 150 for connecting to an air evacuation system such as a factory vacuum exhaust system through an exhaust shut off valve 168. After such connection is made, the gas inlet shut-off valve 166 connected between the gas supply conduit 112 and the gas supply source may be turned on to purge the chamber interior. The purging process may be carried out in a continuous manner, preferably, for a time period of not less than 5 minutes.

The means for evenly distributing the purge gas through the hood body 102 has a plurality of distribution holes 172 spaced apart and disposed within the inner lower wall 146 of the top portion 108 and within the inner side wall 160 of the hood middle portion 110. As shown in FIGS. 4, 6, and 7, a total of eight fluid distribution holes 172 are shown in the inner side wall 160 of the middle portion 110, and a total of five distribution holes 172 are shown disposed within the inner lower wall 146 of the top portion 108, however, the number of distribution holes 172 utilized may be suitably selected and does not need to total 13.

FIG. 4 shows a perspective view of the present invention ventilation hood disposed within a load lock chamber wherein the load lock chamber optionally includes an access door 202 which may be used as an observation means by making the door with a substantially transparent material when the hood body 102 is made of a non-transparent material. The access door 202 may also be provided to advantageously allow a machine operator to access the chamber interior 222 and the chamber cavity. This may be desirable when the purge gas flown from the gas supply conduit 112 are insufficient to clean away the contaminants deposited on the chamber walls and thus a manual cleaning with an air gun becomes necessary.

The load lock chamber may further use a corrosion kit or a diffusion system similar to the diffusion system shown in FIG. 3 in combination with the ventilation hood body to further reduce contaminants in the load lock chamber. The corrosion kit or diffusion system is adapted to heat the wafers disposed within the load lock chamber by applying a heating means to heat and dry the wafers to further prevent outgassing of the processed wafers. The corrosion kit may utilize a heating device such as a wire wrapped around the hood body or may incorporate the heating device into outer surfaces of the hood body.

A method of use of the ventilation hood in accordance with the preferred embodiments disclosed above to prevent contamination within a load lock chamber is disclosed herein by using the hood to perform the following steps. Initially a cassette loaded with processed wafers is loaded into a movable wafer holding device within a load lock chamber. A load-lock process such as pressurizing the wafers within the chamber or heating the wafers using a corrosion resistance kit is performed. Next, hazardous fumes or particles inside the chamber are then exhausted away by the exhaust system. The movable wafer holding device then raises the wafer cassette to the ventilation hood for further processing. The valve 166 is used to purge the hood for at least 5 minutes by introducing compressed air to wafers in cassette to allow outgassing HBr from wafer surfaces and then to vent from the chamber to the atmosphere using the exhaust system. The wafers are then removed from the load lock chamber and transferred to another location for further handling and processing.

A plan view of the gas flow through, the hood 102 using the method disclosed herein is shown in FIG. 5. The arrows show the direction of purge gas flowing through the wafers and directing outgassing of HBR deposited on wafers to flow outwardly towards the atmosphere or the factory exhaust system.

It should be noted that while a load lock chamber for the loading and unloading of wafers and wafer cassettes is illustrated as a specific example for the present invention preferred embodiment, the present invention novel apparatus and method can be utilized on any other sealed chamber that requires wafer handling after a wafer process has been performed. For example, the ventilation hood may be used in combination a diffusion chamber or furnace wherein wafers are heated in a diffusion chamber to prevent further corrosion of the chamber and to reduce outgassing of processed wafers. The diffusion chamber may have a diffusor disposed within the chamber, as illustrated in the prior art FIG. 3. The diffusor is controlled by a gauge 41 and a check valve 39 during the diffusion process.

The use of the present invention novel apparatus and method therefore allows substantially all contaminating particles from a process chamber cavity be carried away from the sealed wafer handling machine and thus insuring high quality IC devices be fabricated and a high yield of the fabrication process be achieved.

The present invention novel ventilation hood therefore not only performs an original function of the hood by exhausting hazardous fumes from inside the sealed chamber, but also performs a chamber cleaning function by reducing contaminating particles in the chamber. Additionally, the ventilation hood may also be used in process industries other than the semiconductor processing industry.

While the present invention has been described in an illustrative manner, it should be understood that the terminology used is intended to be in a nature of words of description rather than of limitation.

Furthermore, while the present invention has been described in terms of a preferred embodiment, it is to be appreciated that those skilled in the art will readily apply these teachings to other possible variations of the inventions.

What is claimed is:

1. A ventilation system for preventing contamination in a sealed wafer handling chamber comprising:
a ventilation hood body, the body having
an open bottom portion, the bottom portion being adapted to sealingly engage a wafer holding device,
a top portion, the top portion forming an airtight horizontally disposed top chamber, and
a middle portion vertically juxtaposed between the top portion and the bottom portion, the middle portion further having an airtight outer side chamber,
wherein the top portion, the middle portion, and the open bottom are in communication and cooperate to define a hood interior, the interior forming a sealed inner chamber when the open bottom portion sealingly engages a wafer holding device;
a gas supply conduit attached to outer side chamber for supplying a purge gas from a gas supply source through the enclosed outer side chamber and into the interior of the hood body;
an exhaust system connected to the top chamber of the hood body for removing the purge gas from the sealed chamber; and
means for evenly distributing a purge gas through the hood body.

2. The ventilation system of claim 1, wherein the sealed inner chamber is in fluid communication with the middle portion outer side chamber, and is in further fluid communication with the top chamber.

3. The ventilation system of claim 2 wherein the top portion horizontally disposed top chamber comprises:
an upper cover for sealably enclosing the top chamber, the upper cover having an exterior upper wall, the exterior upper wall has an outlet in communication with an exhaust tube for communicating a purge gas from the hood to the atmosphere or to a facility exhaust vacuum;
an inner lower wall spaced downwardly apart from the exterior upper wall; and
a side peripheral wall peripherally disposed between the exterior upper wall and the inner lower wall.

4. The ventilation system of claim 3, wherein the upper cover is box-shaped.

5. The ventilation system of claim 3, wherein the distance between the top portion exterior upper wall and a lower peripheral edge of the open bottom portion is 30 cm.

6. The ventilation system of claim 3, wherein the middle portion outer side chamber comprises:
an outer side cover for enclosing the outer side chamber, the outer side cover having an exterior side wall,
an inner side wall spaced inwardly apart from the exterior side wall, and
an outer peripheral wall peripherally disposed between the exterior side wall and the inner side wall; and
an inlet in fluid communication with a gas supply conduit for communicating a purge gas from a gas supply source to the hood interior.

7. The ventilation hood of claim 6, wherein the outer side cover is box-shaped.

8. The ventilation hood of claim 6, wherein the inlet is disposed within the exterior side wall.

9. The ventilation hood of claim 6, wherein the inlet is disposed within an upper surface of the outer peripheral wall.

10. The ventilation system of claim 6, wherein the means for evenly distributing a purge gas through the hood body comprises:
a plurality of distribution holes spaced apart and disposed within the inner lower wall of the top portion and within the inner side wall of the hood middle portion.

11. The ventilation system of claim 1, wherein the sealed wafer handling chamber comprises an observation means through the body.

12. The ventilation system of claim 11, wherein the hood body is substantially optically transparent.

13. The ventilation system of claim 1, wherein the sealed wafer handling chamber is a semiconductor load lock chamber.

14. A ventilation system for preventing contamination in a load lock chamber having a movable wafer holding device, the ventilation system comprising:
a ventilation hood body, the body having an open bottom portion, the bottom portion having a bottom peripheral edge, wherein the bottom peripheral edge has an O-ring adapted to sealingly engage the wafer holding device,
a top portion, the top portion forming an airtight horizontally disposed top chamber, and
a middle portion vertically juxtaposed between the top portion and the bottom portion, the middle portion further having an airtight outer side chamber, wherein the top portion, the middle portion, and the open bottom are in fluid communication with each other and cooperate to define a hood interior, the interior forming a sealed inner chamber when the open bottom portion sealingly engages a wafer holding device;
a gas supply conduit attached to outer side chamber for supplying a purge gas from a gas supply source through the enclosed outer side chamber and into the interior of the hood body;
an exhaust system connected to the top chamber of the hood body for removing the purge gas from the sealed chamber; and
means for evenly distributing a purge gas through the hood body, wherein the means for evenly distributing a purge gas through the hood body evenly distributes flow of the purge gas through the hood interior, the distributing means having a plurality of distribution holes disposed in an airtight manner within the top chamber and within the middle portion side chamber.

15. The ventilation system of claim 14 wherein the top portion horizontally disposed top chamber comprises:
an upper cover for sealably enclosing the top chamber, the upper cover having an exterior upper wall, the exterior upper wall has an outlet in communication with an exhaust tube for communicating a purge gas from the hood to the atmosphere or to a facility exhaust vacuum,
an inner lower wall spaced downwardly apart from the exterior upper wall, and
a side peripheral wall peripherally disposed between the exterior upper wall and the inner lower wall.

16. The ventilation system of claim 15, wherein the middle portion outer side chamber comprises:
an outer side cover for enclosing the outer side chamber, the outer side cover having
an exterior side wall,
an inner side wall spaced inwardly apart from the exterior side wall, and an outer peripheral wall peripherally disposed between the exterior side wall and the inner side wall; and
an inlet in fluid communication with a gas supply conduit for communicating a purge gas from a gas supply source to the hood interior.

17. The ventilation system of claim 14, wherein the load lock chamber further comprises:
means for preventing corrosion of the load lock chamber.

18. A method for using a ventilation system to eliminate load lock contamination particles within a load-lock chamber comprising the steps of:
providing a load-lock chamber in communication with a processing chamber, the load lock chamber having a movable wafer holding member capable of moving between a first retracted position for loading and unloading wafers to a second extended position for ventilating outgassing from wafers;
providing a ventilation hood having a hood body equipped with
an open bottom portion having a peripheral edge adapted to sealingly engage the wafer holding member, wherein the open bottom portion is positioned above the wafer holding member,
a top portion forming an upper chamber, the upper chamber having
an exterior upper wall, the exterior upper wall has an outlet in communication with an exhaust tube for communicating a purge gas from the hood to the atmosphere or to a facility exhaust vacuum, and
an inner lower wall spaced downwardly apart from the exterior upper wall, the inner lower wall having a plurality of distribution holes disposed therewithin,
a middle portion having an outer side chamber, the outer side chamber having
an exterior side wall,
an inner side wall spaced inwardly apart from the exterior side wall, the inner side wall having a plurality of distribution holes disposed therewithin, and
an inlet in fluid communication with a gas supply conduit for communicating a purge gas from a gas supply source to an interior of the hood;
loading a wafer cassette holding a plurality of wafers onto the wafer holding member;
performing a processing operation on the plurality of wafers disposed within the load lock chamber;
moving the wafer holding device to the second extended position to sealingly engage a lower peripheral edge of the hood body open bottom;
flowing a purge gas from the gas supply through the inlet of the outer side chamber, then through the inner side wall distribution holes to the plurality of wafers disposed within the hood interior; and
purging an effluent formed from the purge gas and outgassing of chemicals disposed on the plurality of wafers by exhausting the effluent through the outlet of the top chamber to the exhaust tube in communication with the exhaust system.

19. The method according to claim 18, further comprising the step of flowing the purge gas through the ventilation hood continuously for a time period of not less than five minutes.

20. The method according to claim 18 wherein the purge gas flown through the gas inlet is nitrogen or compressed dry air.

21. The method according to claim 18 further comprising the step of opening a shut-off valve connected in fluid communication with and in between the gas supply conduit and a gas supply source.

22. The method according to claim 18, wherein the fluid flows through the gas inlet under a pressure of about 20 psi.
